(19) United States
(12) Patent Application Publication
(10) Pub. No.: US 2013/0314145 A1
(43) Pub. Date: Nov. 28, 2013

(54) Device for Switching at least one Energy Storage Means

(71) Applicants: Samsung SDI Co., Ltd., Yongin-si (KR); Robert Bosch GmbH, Stuttgart (DE)

(72) Inventors: Bernhard Seubert, Korntal-Muenchingen (DE); Stefan Butzmann, Beilstein (DE)

(73) Assignees: Samsung SDI Co., Ltd., Yongin-si (KR); Robert Bosch GmbH, Stuttgart (DE)

(21) Appl. No.: 13/900,673

(22) Filed: May 23, 2013

(30) Foreign Application Priority Data
May 24, 2012 (DE) 10 2012 208 741.9

(51) Int. Cl. H03K 17/16

(52) U.S. Cl. CPC H03K 17/164
USPC 327/389

(57) ABSTRACT

A device for switching at least one energy storage device includes a parallel circuit of transistors that is connected in series with the energy storage device. Gate terminals of the transistors are connected to one another. At least one of the transistors from the parallel circuit is configured to be operated in avalanche breakdown and has an avalanche voltage which is lower than respective avalanche voltages of the remaining transistors.

This application claims priority under 35 U.S.C. §119 to patent application no. DE 10 2012 208 741.9, filed on May 24, 2012 in Germany, the disclosure of which is incorporated herein by reference in its entirety.

### BACKGROUND

The present disclosure relates to a parallel connection of transistors for switching high currents of loads having an inductive component or of inductances.

Driving components of a circuit by means of transistors, especially by MOSFETs, has been known for a long time from the prior art. Thus, for example, DE 199 13 465 A1 shows a circuit arrangement for driving a power transistor having a so-called push-pull stage which, among other things, consists of two complementary MOSFETs and resistors in each case allocated to one of these.

It is especially when switching inductances or loads with an inductive component, that several transistors must frequently be interconnected in the case of high currents. Thus, a circuit arrangement for reducing switching disturbances in the case of power units in which two transistors are used for driving an inductance is known, for example, from DE 199 13 464 A1. Usually, an even greater number of transistors are also interconnected in parallel in dependence on the inductance or load to be switched.

In FIG. 1, such a circuit arrangement for switching an energy storage means of the prior art, designed as an inductance, is shown. In this arrangement, the inductance is in series with a parallel circuit 20 of transistors 10, the gate terminals 8 of which are connected to one another. The drain terminals 6 of the transistors 10 are connected to one end of the inductance, while the source terminals 4 of the transistors 10 are in each case connected to the ground potential. In addition, a series resistor 2, which can be allocated to the respective gate terminal 8, is in each case located in the connecting paths between the gate terminals 8 and junction 7 of these. At the input 1, a voltage for driving can be applied to the gate terminals 8 of the transistors 10 of the parallel circuit 20 which is indicated in FIG. 1 diagrammatically in the form of rising and falling edges selected purely by way of example.

Typically, all transistors are selected to be of identical type in such circuits in order to achieve uniform switching-on and -off characteristics. In this context, two different types of transistors are available for selection, in particular, for switching inductances or loads having an inductive component. On the one hand, so called VDMOS transistors (vertically diffused MOS transistors), a type of power transistor which can be operated in avalanche breakdown on switching off but switches relatively slowly in comparison with other transistor types and has a high resistance of the drain-source path Rₒₙ in the switched-on state. The second transistor type is so-called Trench FETs, another variant of power transistors. These can switch more rapidly and have a lower resistance of the drain-source path Rₒₙ in the switched-on state compared with the VDMOS transistor. Furthermore, in contrast to VDMOS transistors, Trench FETs are however not designed for being operated in avalanche breakdown. For this reason, Trench FETs are, therefore, not suitable for switching high currents of an inductance or of a load having an inductive component, in a simple parallel circuit although they would be well suited to this purpose due to the aforementioned characteristics.

### SUMMARY

According to the disclosure, a device for switching at least one energy storage means is provided which comprises a parallel circuit, connected in series with the energy storage means, of transistors, the gate terminals of which are connected to one another. At least one of the transistors from the parallel circuit is designed for being operated in avalanche breakdown and has an avalanche voltage which is lower than the respective avalanche voltage of the remaining transistors.

The advantage of such a device for switching an inductance or a load having an inductive component lies in the possibility of selecting those transistors which are not designed for being operated in avalanche breakdown, with electrical behavior optimized compared with the prior art and, for example, more cost-effective transistors. When the transistors are switched off, the transistor which is designed for being operated in avalanche breakdown changes, in the case of high currents to be switched, into avalanche breakdown since it has the lowest avalanche voltage of all transistors installed in the device. For the remaining transistors of the device, an operation in avalanche breakdown does not occur so that for these, transistors can also be selected which are not specified for operation in avalanche breakdown.

In a preferred embodiment, the transistors of the parallel circuit are constructed as MOSFETs. The advantage in using MOSFETs is, among other things, their integration or packaging density which is high in comparison with transistors of other technologies. Furthermore, MOSFETs have, for example in comparison with bipolar transistors, a low resistance of the drain-source path Rₒₙ and are cost effective when implemented in the substrate.

The transistors of the parallel circuit are preferably constructed as power transistors. Power transistors can switch or control high currents or powers and are more compact than relays or breakers. They have a very large gain factor and a low on-state resistance.

In a preferred embodiment, the transistor having the lower avalanche voltage is constructed as a VDMOS transistor. Transistors of this type from the series of MOS transistors are particularly well suited for operation in avalanche breakdown. In addition VDMOS transistors have a high breakdown voltage and provide for a high current flow for driving loads.

The transistors having the higher avalanche voltage are preferably constructed as Trench FETs. Trench FETs are characterized by a high switching speed and by a low resistance of the drain-source path.

In a preferred embodiment, the energy storage means is constructed as inductance. These are particularly well suited as buffer memories and are cost effective.

Furthermore, it is preferred to construct the energy storage means as a load having an inductive component.

The source terminals of the transistors of the parallel circuit are preferably connected to a constant potential. Particularly preferably, the source terminal in a source circuit is connected to ground. In such a circuit configuration, the very high input resistance rₑ, among other things, of such a circuit configuration is of advantage.

In a preferred embodiment, the drain terminals of the transistors of the parallel circuit are connected to one end of the energy storage means. The electrical behavior of the device for switching an energy storage means is optimized by such a circuit configuration.

Preferably, a series resistor is arranged connected in series with the gate terminal before at least one gate terminal of a transistor. Due to the parasitic gate-drain capacitance of some transistors, especially MOS transistors, a negative impedance can be generated at the gate terminal itself in the case of certain currents at and from the gate terminal. The inductance formed by the feed line to the gate, together with the parasitic capacitances of the respective transistor, may then form a parasitic resonant circuit which is excited in dependence on the current flowing. The formation of such an excited parasitic resonant circuit can be counteracted by using a series resistor before the gate terminal.

### BRIEF DESCRIPTION OF THE DRAWINGS

Exemplary embodiments of the disclosure will be explained in greater detail with reference to the drawings and the description following. In the drawings:

FIG. 1 shows a device for switching an inductance of the prior art, and

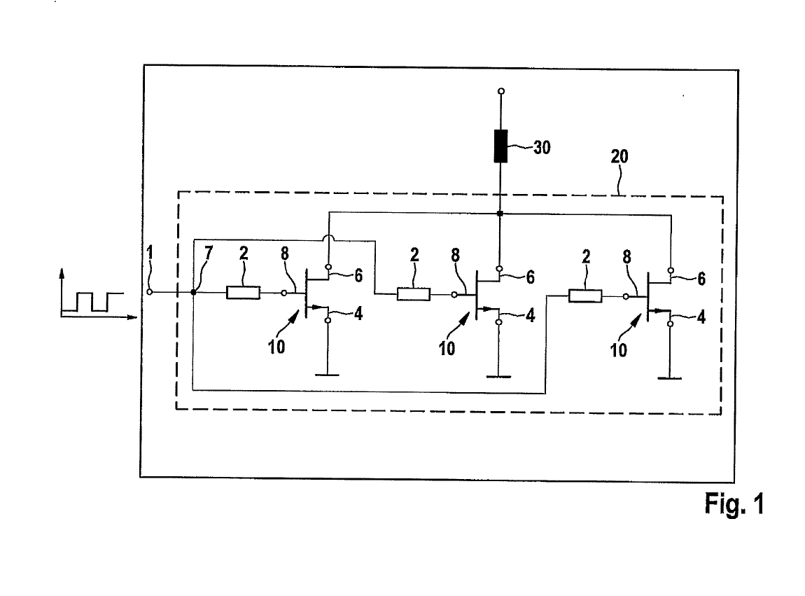

FIG. 2 shows a device according to the disclosure for switching an energy storage means.

### DETAILED DESCRIPTION

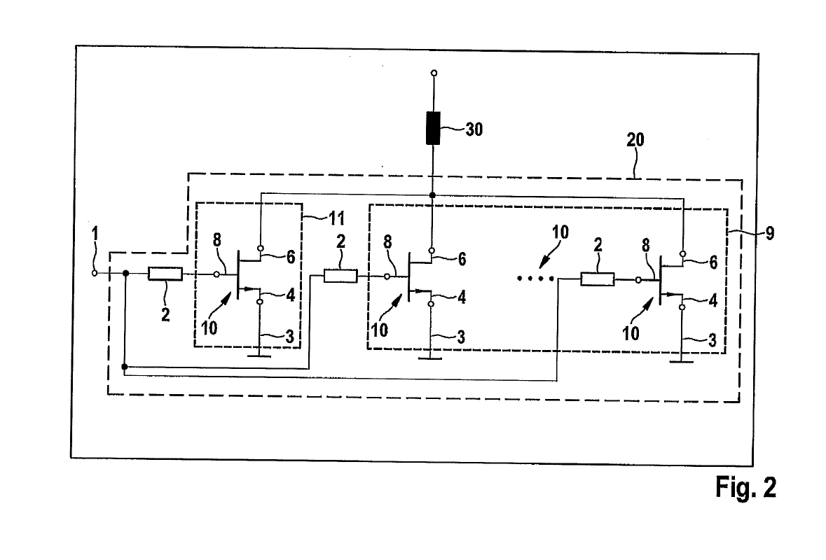

FIG. 2 shows a device according to the disclosure for switching an energy storage means 30, which is also referred to as an energy storage device. In this exemplary embodiment, the energy storage means 30 is designed as inductance which is located in series with a parallel circuit 20 of six transistors 10, three of which are shown in FIG. 2, whilst the remaining transistors 10 not shown are indicated via a dotted line. In this exemplary embodiment, the drain terminals 6 of the transistors 10 are here connected to the same end of the energy storage means 30 whilst the source terminals 4 of the transistors 10 are connected to ground 3.

One of the transistors 10 of the parallel circuit is constructed as VDMOS transistor 11 (vertically diffused MOS transistor) whilst the remaining transistors from the parallel circuit are designed as Trench FETs 9. The VDMOS transistor 11 is designed for being operated in avalanche breakdown and has an avalanche voltage which is lower than the respective avalanche voltages of the remaining transistors 10 of the parallel circuit 20. In other words, the VDMOS transistor 11 can be operated reversibly in avalanche breakdown over a long period of time which, in the present exemplary embodiment, is related to the product life of the circuit in which the device according to the disclosure is installed, without being damaged. In the present exemplary embodiment, the Trench FETs 9 are all selected to be of the same type and constructed approximately identically. They have an avalanche voltage which is above the avalanche voltage of the VDMOS transistor 11. In the exemplary embodiment of the device according to the disclosure, shown in FIG. 2, a series resistor 2 is in each case connected in series with in each case one gate terminal 8 of a transistor 10 of the parallel circuit 20. However, it is also possible to implement devices according to the disclosure without such series resistors 2 or having only some series resistors 2 before a selected number of transistors 10 within the parallel circuit 20. The gate terminals 8 of all transistors 10 of the parallel circuit 20 are connected to one another at the connections of the respective series resistors 2 which face away from the respective gate terminals 8 of the respective transistors 10 and combined in a common input 1. Expressed in other words, a drive signal which is applied to the input 1 is conducted via the respective series resistors 2 to the respective gate terminals 8 of the transistors 10 of the parallel circuit 20.

If the parallel circuit 20 is then used for switching high currents provided by the inductance, an operation in avalanche breakdown will occur in the case of VDMOS transistors 11 when the transistors 10 are switched off. At this time, the Trench FETs 9 are already switched off since these, in comparison with VDMOS transistors 11, are a type of transistor having a faster switching characteristic and their avalanche voltage is greater than that of the VDMOS transistor 11, that is to say they are already switched into the off state. Once the current flow from the inductance via the parallel circuit 20 has taken place, the VDMOS transistor 11 changes back from avalanche mode into normal mode and the device is again in its initial state.

In the exemplary embodiment shown in FIG. 2, the VDMOS transistor 11 is on the outside within the parallel circuit 20 but can also be at any other position.

However, the terminals 4, 6, 8 of all transistors 10 can also be connected to in each case another constant or also non-constant potential.

Both the type and the number of energy storage means 30 to be switched are selected purely by way of example in the present exemplary embodiment and are not restricted to inductances. It is also possible to switch other and more components such as, for example, loads having an inductive component which are interconnected in parallel or in series with one another purely by way of example, by means of the transistors 10 of the parallel circuit 20.

What is claimed is:

1. A device for switching at least one energy storage device, comprising:
a parallel circuit connected in series with the energy storage device, the parallel circuit including a plurality of transistors,
wherein each transistor of the plurality of transistors includes a gate terminal,
wherein the gate terminals of the plurality of transistors are connected to one another,
wherein at least one transistor of the plurality of transistors is configured for operation in avalanche breakdown and defines an avalanche voltage, and
wherein the avalanche voltage of the at least one transistor is lower than a respective avalanche voltage of the other transistors of the plurality of transistors.

2. The device according to claim 1, wherein the transistors of the plurality of transistors are MOSFETs.

3. The device according to claim 1, wherein the transistors of the plurality of transistors are power transistors.

4. The device according to claim 3, wherein the at least one transistor is a VDMOS transistor.

5. The device according to claim 3, wherein the other transistors of the plurality of transistors are Trench FETs.

6. The device according to claim 1, wherein the energy storage device is constructed as inductance.

7. The device according to claim 1, wherein the energy storage device includes a load having an inductive component.

8. The device according to claim 1, wherein:
each transistor of the plurality of transistors includes a source terminal, and
the source terminals of the plurality of transistors are connected to a constant potential.

9. The device according to claim 8, wherein:
each transistor of the plurality of transistors includes a drain terminal, and
the drain terminals of the plurality of transistors are connected to an end of the energy storage device.

10. The device according to claim 1, further comprising:
a series resistor connected in series with one gate terminal of the transistors of the plurality of transistors,
wherein the series resistor is positioned before the one gate terminal of the transistors of the plurality of transistors.
